(19) United States
(12) Patent Application Publication
(10) Pub. No.: US 2024/0282857 A1
(43) Pub. Date: Aug. 22, 2024

(54) SEMICONDUCTOR DEVICE, PHOTOELECTRIC CONVERSION DEVICE, AND ELECTRONIC APPARATUS

(71) Applicant: Canon Kabushiki Kaisha, Tokyo (JP)

(72) Inventor: TASUKU KANEDA, Kanagawa (JP)

(21) Appl. No.: 18/439,831

(22) Filed: Feb. 13, 2024

(30) Foreign Application Priority Data
Feb. 16, 2023 (JP) 2023-022639

(51) Int. Cl. H01L 29/78; H01L 27/088; H01L 27/146

(52) U.S. Cl. CPC H01L 29/7833; H01L 27/088; H01L 27/14612; H01L 27/14627

(57) ABSTRACT

A semiconductor device including first and second transistors is provided. The first transistor includes first and second regions each being arranged between corresponding one of diffusion regions and a channel region and having a lower concentration than the diffusion regions, and a first length of the first region is longer than a length of the second region. The second transistor includes third and fourth regions each being arranged between corresponding one of diffusion regions and a channel region and having a lower concentration than the diffusion regions, and a third length of the third region is longer than a length of the fourth region. A depth of the first region is equal to a depth of the third region, the third length is longer than the first length, and a higher voltage than the first transistor is applied to the second transistor.

### BACKGROUND OF THE INVENTION

### Field of the Invention

The present invention relates to a semiconductor device, a photoelectric conversion device, and an electronic apparatus.

### Description of the Related Art

Japanese Patent Laid-Open No. 2000-100964 describes a semiconductor device in which the offset length of an LDD structure is different between a transistor to which a high voltage is applied and another transistor arranged in one substrate.

### SUMMARY OF THE INVENTION

In each transistor described in Japanese Patent Laid-Open No. 2000-100964, the offset length on the drain side is equal to the offset length on the source side. Consider a case in which one of the drain and the source requires a higher breakdown voltage than the other. In this case, by setting the offset length while considering the breakdown voltage of one of the drain and the source, the reliability of the transistor improves. On the other hand, the offset length in the other of the drain and the source becomes longer than required. Hence, the ON current decreases, and the characteristics of the transistor can be deteriorated.

Some embodiments of the present invention provide a technique advantageous in achieving both an improvement in reliability of a semiconductor device and an improvement in characteristics thereof.

According to some embodiments, a semiconductor device in which a first transistor and a second transistor having different operation voltages are arranged in a substrate, wherein the first transistor comprises a first region and a second region each being arranged between corresponding one of two diffusion regions functioning as one of a source and a drain and a channel region and having a lower impurity concentration than the two diffusion regions of the first transistor, and a first length of the first region is longer than a second length of the second region in a direction in which a current flows through the first transistor, the second transistor comprises a third region and a fourth region each being arranged between corresponding one of two diffusion regions functioning as one of a source and a drain and a channel region and having a lower impurity concentration than the two diffusion regions of the second transistor, and a third length of the third region is longer than a fourth length of the fourth region in a direction in which a current flows through the second transistor, a depth of the first region is equal to a depth of the third region, and the third length is longer than the first length, and a higher voltage than the first transistor is applied to the second transistor, is provided.

According to some other embodiments, a semiconductor device in which a first transistor and a second transistor of a first conductivity type and a third transistor and a fourth transistor of a second conductivity type different from the first conductivity type are arranged in a substrate, wherein operation voltages of the first transistor and the third transistor are different from operation voltages of the second transistor and the fourth transistor, the first transistor comprises a first region and a second region each being arranged between corresponding one of two diffusion regions functioning as one of a source and a drain and a channel region, and having a lower impurity concentration than the two diffusion regions of the first transistor, and a first length of the first region is longer than a second length of the second region in a direction in which a current flows through the first transistor, the second transistor comprises a third region and a fourth region each being arranged between corresponding one of two diffusion regions functioning as one of a source and a drain and a channel region and having a lower impurity concentration than the two diffusion regions of the second transistor, and a third length of the third region is longer than a fourth length of the fourth region in a direction in which a current flows through the second transistor, the third transistor comprises a fifth region and a sixth region each being arranged between corresponding one of two diffusion regions functioning as one of a source and a drain and a channel region and having a lower impurity concentration than the two diffusion regions of the third transistor, and a fifth length of the fifth region is longer than a sixth length of the sixth region in a direction in which a current flows through the third transistor, the fourth transistor comprises a seventh region and an eighth region each being arranged between corresponding one of two diffusion regions functioning as one of a source and a drain and a channel region and having a lower impurity concentration than the two diffusion regions of the fourth transistor, and a seventh length of the seventh region is longer than an eighth length of the eighth region in a direction in which a current flows through the fourth transistor, and in the direction, a difference between the first length and the third length is larger than a difference between the fifth length and the seventh length, is provided.

Further features of the present invention will become apparent from the following description of exemplary embodiments (with reference to the attached drawings).

### BRIEF DESCRIPTION OF THE DRAWINGS

FIG. 1 is a view showing an example of the arrangement of a semiconductor device according to an embodiment;

FIG. 2 is a sectional view showing an example of the arrangement of the semiconductor device shown in FIG. 1;

FIG. 3 is a sectional view showing an example of the arrangement of the semiconductor device shown in FIG. 1;

FIGS. 4A to 4C are views showing an example of the impurity concentration distribution of the semiconductor device shown in FIG. 1;

FIGS. 5A and 5B are views showing an example of the impurity concentration distribution of the semiconductor device shown in FIG. 1;

FIG. 6 is a sectional view showing an example of the arrangement of the semiconductor device shown in FIG. 1;

FIG. 7 is a sectional view showing an example of the arrangement of the semiconductor device shown in FIG. 1;

FIGS. 8A and 8B are sectional views showing an example of the arrangement of the pixel of the semiconductor device shown in FIG. 1;

FIGS. 9A to 9C are views showing an example of an image forming device using the semiconductor device according to the embodiment;

FIG. 10 is a view showing an example of a display device using the semiconductor device according to the embodiment;

FIG. 11 is a view showing an example of a photoelectric conversion device using the semiconductor device according to the embodiment;

FIG. 12 is a view showing an example of an electronic apparatus using the semiconductor device according to the embodiment;

FIGS. 13A and 13B are views each showing an example of a display device using the semiconductor device according to the embodiment;

FIG. 14 is a view showing an example of an illumination device using the semiconductor device according to the embodiment;

FIG. 15 is a view showing an example of a moving body using the semiconductor device according to the embodiment; and

FIGS. 16A and 16B are views each showing an example of a wearable device using the semiconductor device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

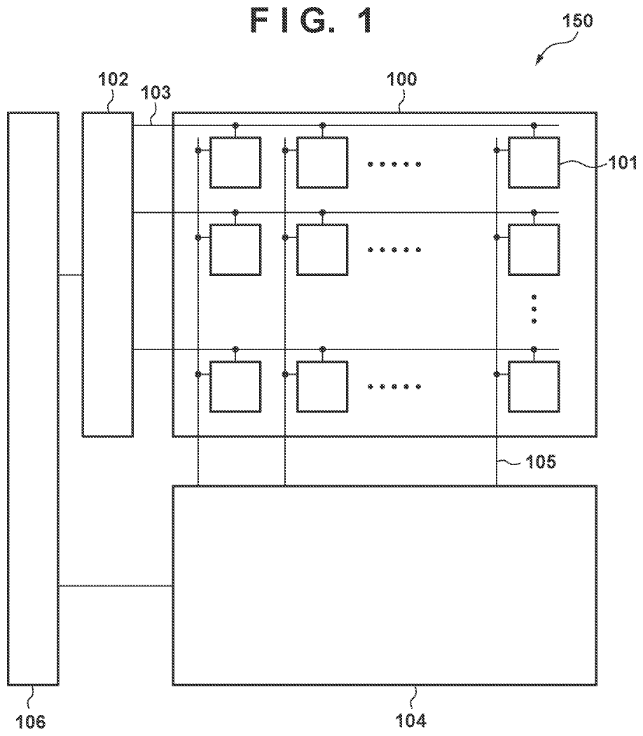

With reference to FIGS. 1 to 7, a semiconductor device according to an embodiment of the present disclosure will be described. In the embodiment described below, a description will be given while taking a light emitting device as an example of the semiconductor device. However, the present disclosure is not limited to this, and the present disclosure is applicable to a processing device, a storage device, a photoelectric conversion device, and the like, each including a semiconductor element, of various logic circuits, storage circuits, pixel circuits, and the like. More specifically, the present disclosure is applicable to all semiconductor devices each including a transistor having the LDD structure (offset structure) described below.

FIG. 1 is a view showing an example of the arrangement of a light emitting device 150 as an example of the semiconductor device in this embodiment. The light emitting device 150 includes a pixel array 100 where a plurality of pixels 101 each including a light emitting element are arranged, and a peripheral circuit for driving the plurality of pixels 101. The plurality of pixels 101 are arranged in an array in the pixel array 100. The peripheral circuit can include a vertical scanning circuit 102, a signal output circuit 104, and a control circuit 106. Each pixel 101 is supplied with a control signal from the vertical scanning circuit 102 via a scanning line 103, and supplied with a luminance signal from the signal output circuit 104 via a signal line 105. The vertical scanning circuit 102 and the signal output circuit 104 are controlled by the control circuit 106. The signal output circuit 104 converts the image data scanned by a horizontal scanning circuit and input to each column into an analog signal voltage, and outputs a luminance signal corresponding to the analog signal voltage to the signal line 105.

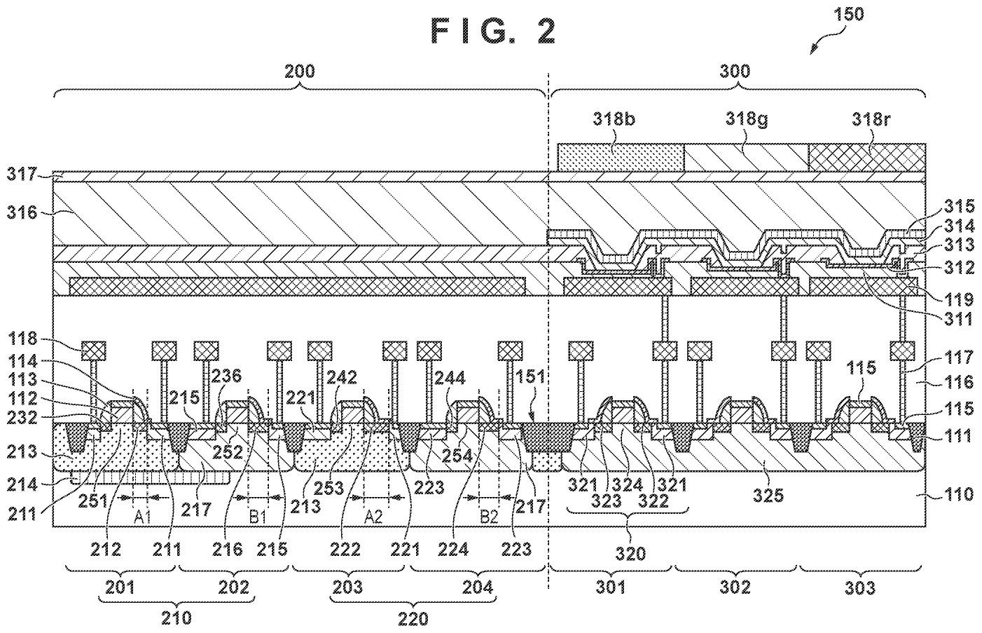

FIG. 2 shows an example of the sectional structure of elements mounted in the light emitting device 150 in this embodiment. In the arrangement shown in FIG. 2, the light emitting device 150 is formed in a substrate 110 and on a surface 151 of the substrate 110. The substrate 110 can be, for example, a semiconductor substrate using silicon or the like.

A shallow trench isolation (STI) 111 used to isolate elements such as transistors is arranged in the substrate 110. However, isolation of the elements is not limited to the use of the STI 111. The elements may be isolated by, for example, a Local Oxidation of Silicon (LOCOS), deep trench isolation (DTI), or diffusion isolation by impurity doping.

In the substrate 110, a peripheral circuit 200 formed by the vertical scanning circuit 102, the signal output circuit 104, and the like, and a pixel circuit 300 formed by the pixel array 100 including the plurality of pixels 101 each of which includes the light emitting element are arranged. Transistors are formed in the peripheral circuit 200 and the pixel circuit 300. Each transistor includes, for example, a gate electrode 112, a side wall 113, and a silicide prevention film 114. Further, for example, in each transistor, a silicide 115 is formed in a portion where the silicide prevention film 114 is not arranged and the substrate 110 (for example, silicon) is exposed. On the surface 151 of the substrate 110, an interlayer insulating film 116, a plug 117, a wiring pattern 118, an electrode 119, and the like can be arranged. For the interlayer insulating film 116, an inorganic material such as silicon oxide, silicon nitride, or silicon carbide, or an organic material such as a resin can be used. The plug 117, the wiring pattern 118, and the electrode 119 can be formed of a metal such as aluminum, tungsten, silver, copper, or titanium, or a compound thereof.

The pixel circuit 300 can be divided into, for example, a pixel 301 that emits blue light, a pixel 302 that emits green light, and a pixel 303 that emits red light. Each of the pixels 301 to 303 can also be called a sub pixel. Each of the pixels 301 to 303 corresponds to the pixel 101 described above. On the electrode 119 arranged in each of the pixels 301 to 303, an optical adjustment layer 311 having a height satisfying the optical interference condition for the corresponding light emission color, an electrode 312, a pixel isolation layer 313, a functional layer 314 including a light emitting layer, and an electrode 315 are arranged. On the electrode 315, a sealing film 316, a planarization layer 317, and the like are formed. The light emitting element described above is formed while including the electrode 312, the functional layer 314 including the light emitting layer, the electrode 315, and the like. On the planarization layer 317, a blue color filter 318b, a green color filter 318g, and a red color filter 318r having the spectral characteristics corresponding to the pixels 301 to 303, respectively, are arranged. With this arrangement, light can be emitted in accordance with the luminance signal of each of the pixels 301 to 303.

In the peripheral circuit 200, elements including a low-voltage operation transistor 210 and a high-voltage operation transistor 220, which have different operation voltages, are arranged. The high-voltage operation transistor 220 is a transistor to which a higher voltage than the low-voltage operation transistor 210 is applied. Here, a higher voltage than the low-voltage operation transistor 210 is not always applied to the high-voltage operation transistor 220. The maximum voltage applied to the high-voltage operation transistor 220 is higher than that of the low-voltage operation transistor 210. FIG. 2 shows, as the low-voltage operation transistors 210, a transistor 201 which is an n-type (n-channel) MIS transistor, and a transistor 202 which is a p-type (p-channel) MIS transistor. Further, as the high-voltage operation transistors 220, a transistor 203 which is an n-type MIS transistor, and a transistor 204 which is a p-type MIS transistor are shown.

The transistor 201 includes two n-type diffusion regions 211 functioning as the source or the drain, and n-type regions 212 and 232 each being arranged between corresponding one of the two diffusion regions 211 and a channel region 251 and having a lower impurity concentration than the diffusion regions 211. It can also be said that the transistor 201 has an LDD structure including the low impurity concentration regions 212 and 232. In the direction in which a current flows through the transistor 201 (the horizontal direction in the arrangement shown in FIG. 2), the length of the region 212 is longer than the length of the region 232. The diffusion regions 211 and the regions 212 and 232 of the transistor 201 are formed in a p-type well 213 provided in the substrate 110. An n-type deep well 214 is arranged at a position deeper than the well 213 so as to contact the well 213.

The transistor 202 includes two p-type diffusion regions 215 functioning as the source or the drain, and p-type regions 216 and 236 each being arranged between the corresponding one of the two diffusion regions 215 and a channel region 252 and having a lower impurity concentration than the diffusion regions 215. It can also be said that the transistor 202 has an LDD structure including the low impurity concentration regions 216 and 236. In the direction in which a current flows through the transistor 202 (the horizontal direction in the arrangement shown in FIG. 2), the length of the region 216 is longer than the length of the region 236. The diffusion regions 215 and the regions 216 and 236 of the transistor 202 are formed in an n-type well 217 provided in the substrate 110.

The transistor 203 includes two n-type diffusion regions 221 functioning as the source or the drain, and n-type regions 222 and 242 each being arranged between the corresponding one of the two diffusion regions 221 and a channel region 253 and having a lower impurity concentration than the diffusion regions 221. It can also be said that the transistor 203 has an LDD structure including the low impurity concentration regions 222 and 242. In the direction in which a current flows through the transistor 203 (the horizontal direction in the arrangement shown in FIG. 2), the length of the region 222 is longer than the length of the region 242. The diffusion regions 221 and the regions 222 and 232 of the transistor 203 are formed in the p-type well 213 provided in the substrate 110.

The transistor 204 includes two p-type diffusion regions 223 functioning as the source or the drain, and p-type regions 224 and 244 each being arranged between the corresponding one of the two diffusion regions 223 and a channel region 254 and having a lower impurity concentration than the diffusion regions 223. It can also be said that the transistor 204 has an LDD structure including the low impurity concentration regions 224 and 244. In the direction in which a current flows through the transistor 204 (the horizontal direction in the arrangement shown in FIG. 2), the length of the region 224 is longer than the length of the region 244. The diffusion regions 223 and the regions 224 and 244 of the transistor 204 are formed in the n-type well 217 provided in the substrate 110.

Transistors are also arranged in the pixel circuit 300. The transistor arranged in the pixel circuit 300 may be an n-type transistor or a p-type transistor. The transistor arranged in the pixel circuit 300 may have an arrangement similar to that of the above-described low-voltage operation transistor 210 or high-voltage operation transistor 220. As the transistor arranged in the pixel circuit 300, FIG. 2 shows a transistor 320 which is a p-type MIS transistor. The transistor 320 includes two p-type diffusion regions 321 functioning as the source or the drain, and p-type regions 322 and 323 each being arranged between the corresponding one of the two diffusion regions 321 and a channel region 324 and having a lower impurity concentration than the diffusion regions 321. It can also be said that the transistor 320 has an LDD structure including the low impurity concentration regions 322 and 323. In the direction in which a current flows through the transistor 320 (the horizontal direction in the arrangement shown in FIG. 2), the length of the region 322 is equal to the length of the region 323. The diffusion regions 321 and the regions 322 and 323 of the transistor 320 are formed in an n-type well 325 provided in the substrate 110.

In the peripheral region 200 and the pixel circuit 300, the diffusion regions 211, 215, 221, 223, and 321 each functioning as the source or the drain can be arranged while being offset by an arbitrary distance from directly below the gate electrode 112 by using the regions 212, 232, 216, 236, 222, 242, 224, 244, 322, and 323, respectively. In the transistor 201 as the n-type low-voltage operation transistor 210, an offset length A1 by which one diffusion region 211 is offset from directly below the gate electrode 112 may be set to, for example, 0.15 μm. In other words, the length of the region 212 in the direction in which a current flows in the transistor 201 may be 0.15 μm. In the transistor 203 as the n-type high-voltage operation transistor 220, an offset length A2 by which one diffusion region 221 is offset from directly below the gate electrode 112 may be set to, for example, 0.6 μm. In other words, the length of the region 222 in the direction in which a current flows in the transistor 203 may be 0.6 μm. In the transistor 202 as the p-type low-voltage operation transistor 210, an offset length B1 by which one diffusion region 215 is offset from directly below the gate electrode 112 may be set to, for example, 0.2 μm. In other words, the length of the region 216 in the direction in which a current flows in the transistor 202 may be 0.2 μm. In the transistor 204 as the p-type high-voltage operation transistor 220, an offset length B2 by which one diffusion region 223 is offset from directly below the gate electrode 112 may be set to, for example, 0.2 μm. In other words, the length of the region 224 in the direction in which a current flows in the transistor 204 may be 0.2 μm. In this manner, the length difference between the region 212 of the n-type transistor 201 and the region 222 of the n-type transistor 203 may be larger than the length difference between the region 216 of the p-type transistor 202 and the region 224 of the p-type transistor 204. Each of the offset lengths A1, A2, B1, and B2 is not limited to the above-described value, and an appropriate length is set in accordance with the characteristics required for each transistor.

Next, the offset lengths A1 and A2 of the n-type transistors 201 and 203 will be described. The offset lengths A1 and A2 are set longer as the transistors operate at a higher voltage (a higher voltage is applied thereto). Accordingly, the maximum potential applied to the contact region of the diffusion region 221 functioning as the drain moderately drops in the high-resistance diffusion layer region of the n-type region 222. As a result, the electric field intensity in the p-n junction interface near the gate electrode 112 and between the region 222 and the well 213 decreases. Hence, the breakdown voltage and the reliability can be ensured. On the other hand, the offset lengths are set shorter as the transistors operate at a lower voltage. Accordingly, it is possible to shorten the current path of the low impurity concentration and high resistance region 212. Hence, the layout area can be reduced while suppressing a degradation of drivability. That is, by adjusting the offset length, it is possible to control the characteristics according to the kind of the transistor. Thus, improvements in reliability and characteristics of the light emitting device 150 are implemented.

The n-type diffusion region 211 and diffusion region 221 need not be formed with different impurity concentrations, and may be formed with the same concentration and depth. Similarly, the n-type regions 212 and 232 and the n-type regions 222 and 242 need not be formed with different impurity concentrations, and may be formed with the same concentration and depth. That is, the impurity concentration of the diffusion region 211 may be equal to the impurity concentration of the diffusion region 221, and the depth of the diffusion region 211 may be equal to the depth of the diffusion region 221. Similarly, the impurity concentrations of the regions 212 and 232 may be equal to the impurity concentrations of the regions 222 and 242, and the depths of the regions 212 and 232 may be equal to the depths of the regions 222 and 242. With this, in a step of forming the diffusion regions 211 and 221 and in a step of forming the regions 212, 232, 222, and 242, it is possible to manufacture the light emitting device 150 without increasing the number of steps. Similarly, the p-type diffusion region 215 and diffusion region 223 need not be formed with different impurity concentrations, and may be formed with the same concentration and depth. Further, the p-type regions 216 and 236 and regions 224 and 244 need not be formed with different impurity concentrations, and may be formed with the same concentration and depth.

For example, the low-voltage operation transistor 210 can be a 5V-driven transistor, and the high-voltage operation transistor 220 can be a 10V-driven transistor. That is, a case is assumed in which the difference between the maximum voltage applied to the low-voltage operation transistor 210 and the maximum voltage applied to the high-voltage operation transistor 220 is 5 V or more. Normally, when forming, on the same substrate, transistors to which different potential differences (voltages) are applied, from the viewpoint of ensuring the breakdown voltage and the reliability, it is common to form, particularly, the light-doped regions 212 and 232 and regions 222 and 242, each having a low impurity concentration, with different concentrations and depths. On the other hand, in this embodiment, the offset length is individually adjusted in accordance with the characteristics required for the transistor of each operation voltage. For example, as has been described above, in the direction in which a current flows through the transistors 201 and 203, the length of the region 222 of the transistor 203 (offset length A2) is longer than the length of the region 212 of the transistor 201 (offset length A1) by 0.4 μm or more. With this, even in a case in which, between the transistor 201 and the transistor 203 having different operation voltages, the diffusion region 211 and the diffusion region 221 are formed with the same concentration and depth and the regions 212 and 232 and the regions 222 and 242 are formed with the same concentration and depth, desired characteristics can be obtained. In order to simultaneously form the diffusion region 211 and the diffusion region 221, and simultaneously form the regions 212 and 232 and the regions 222 and 242, it is necessary to design the relationship of impurity concentration and depth among the diffusion regions 211 and 221, the regions 212, 232, 222, and 242, and the channel regions 251 and 253 within a range in which the characteristics are compatible. The relationship of impurity concentration and depth among the diffusion regions 211 and 221 and the regions 212, 232, 222, and 242 will be described later.

On the other hand, depending on the specifications of the operation voltages of the low-voltage operation transistor 210 and the high-voltage operation transistor 220 and the potential difference therebetween, there is a case in which it is difficult to simultaneously form the diffusion region 211 and the diffusion region 221, the diffusion region 215 and the diffusion region 223, the regions 212 and 232 and the regions 222 and 242, and the regions 216 and 236 and the regions 224 and 244, respectively. In this case, for example, in accordance with the operation voltages, some or all of the diffusion region 211 and the diffusion region 221, the diffusion region 215 and the diffusion region 223, the regions 212 and 232 and the regions 222 and 242, the regions 216 and 236 and the regions 224 and 244 may be formed with different concentrations and depths.

In the arrangement shown in FIG. 2, for example, the length of the region 232 in the direction in which a current flows in the transistor 201 as the n-type low-voltage operation transistor 210 may be equal to the length of the region 242 in the direction in which a current flows in the transistor 203 as the n-type high-voltage operation transistor 220. Further, for example, the length of the region 236 in the direction in which a current flows in the transistor 202 as the p-type low-voltage operation transistor 210 may be equal to the length of the region 244 in the direction in which a current flows in the transistor 204 as the p-type high-voltage operation transistor 220. For example, in a case in which only the potential of GND is applied to the diffusion regions 211, 215, 221, and 223 functioning as the sources of the transistors 201 to 204, respectively, the offset length given by the region 232 may be equal to the offset length given by the region 242. Similarly, the offset length given by the region 236 may be equal to the offset length given by the region 244.

Further, in the arrangement shown in FIG. 2, the lengths of the regions 322 and 323 in the direction in which a current flows in the p-type transistor 320 arranged in the pixel circuit 300 may be longer than the length of the region 232 in the direction in which a current flows in the transistor 201 as the n-type low-voltage operation transistor 210. This is because the transistor 320 arranged in the pixel circuit 300 more often operates by a higher voltage than the low-voltage operation transistor 210 being applied. Similarly, the lengths of the regions 322 and 323 in the direction in which a current flows in the p-type transistor 320 arranged in the pixel circuit 300 may be longer than the length of the region 216 in the direction in which a current flows in the transistor 202 as the p-type low-voltage operation transistor 210. In this case, for example, the impurity concentration of the region 216 may be equal to the impurity concentrations of the regions 322 and 323. Further, for example, the depth of the region 216 may be equal to the depths of the regions 322 and 323. With this, it is possible to reduce the manufacturing step. However, the present invention is not limited to this, and the offset lengths, impurity concentrations, and depths of the regions 322 and 323 may be set, as appropriate, in accordance with the characteristics required for the pixel circuit 300.

The higher voltage the transistor operates at, the longer the gate length can be set for the gate electrode 112 of the transistor including the transistors 201 to 204 and 320 used in the peripheral circuit 200 and the pixel circuit 300. In this case, it is possible to suppress the OFF current and control the threshold regardless of the operation voltage of each transistor.

In the transistors 201 to 204 arranged in the peripheral circuit 200, the gate electrode 112 may be formed of n-type polycrystalline silicon regardless of whether the transistor is the n-type transistor or the p-type transistor. For example, the impurity concentration of the polycrystalline silicon may be 1×10²¹ cm⁻³ or more. In this case, the threshold voltages of the p-type transistors 202 and 204 can be shifted toward the negative voltage direction due to the work function of polycrystalline silicon. Accordingly, even in a case in which the channel regions 252 and 254 of the p-type transistors 202 and 204 are not heavily implanted with impurities, the threshold can be maintained at a negative voltage. Since the channel regions 252 and 254 are not heavily introduced with impurities, as a result, variations between the transistors can be suppressed. On the other hand, for the purpose of controlling the threshold voltage of the p-type transistor, p-type polycrystalline silicon may be used for the gate electrode 112 in each of the p-type transistors arranged in the pixel circuit 300 and the peripheral circuit 200.

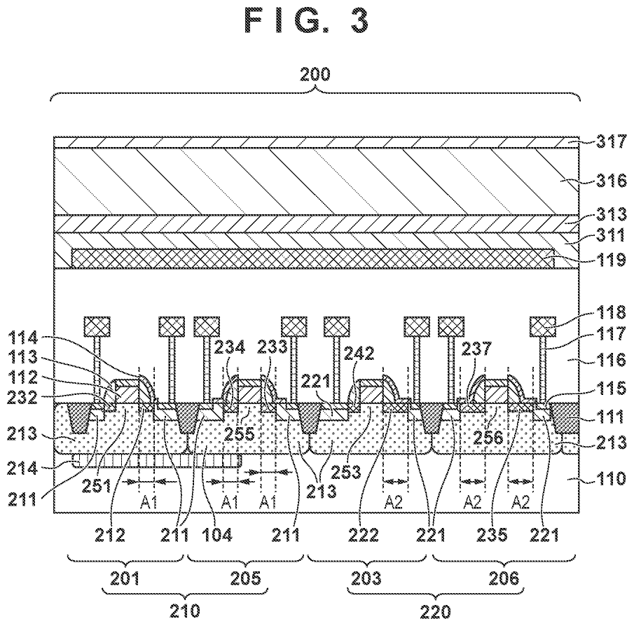

FIG. 3 shows an example of the sectional structure of elements mounted in the peripheral circuit 200 of the light emitting device 150 in this embodiment. In addition to the transistors 201 and 203 described above, FIG. 3 shows a transistor 205 included in the low-voltage operation transistor 210 and a transistor 206 included in the high-voltage operation transistor 220. As has been described above, in the transistor 201 (203), the length of the region 212 (222) and the length of the region 232 (242) in the direction in which a current flows in the transistor 201 (203) are different from each other, so that the transistor 201 (203) has a structure in which the offset length of the LDD structure is different between the drain side and the source side. On the other hand, in the transistor 205 (206), the length of a region 233 (235) and the length of a region 234 (237) in the direction in which a current flows in the transistor are equal to each other, so that the transistor 205 (206) has a structure in which the offset length of the LDD structure is the same between the drain side and the source side. Here, the transistor in which the offset length is different between the drain side and the source side, like the transistors 201 to 204, is sometimes referred to as a single-side offset transistor in the following description. Further, the transistor in which the offset length is the same between the drain side and the source side, like the transistors 205 and 206, is sometimes referred to as a double-side offset transistor in the following description. In this embodiment, both the single-side offset transistor and the double-side offset transistor may be arranged in the light emitting device 150. As shown in FIG. 3, both the single-side offset transistor and the double-side offset transistor may be arranged in both the low-voltage operation transistor 210 and the high-voltage operation transistor 220. Alternatively, for example, both the single-side offset transistor and the double-side offset transistor may be arranged in one of the low-voltage operation transistor 210 and the high-voltage operation transistor 220.

In the portion where the offset length is long (in the portion where each of the regions 212, 222, 233, 234, 235, and 237 is arranged), the silicide prevention film 114 is arranged such that each of the regions 212, 222, 233, 234, 235, and 237 does not contact the silicide 115. The offset lengths, which are the lengths of the regions 212, 233, and 234 in the direction in which a current flows, may be the same offset length A1 in the single-side offset transistor and the double-side offset transistor. Further, the offset lengths, which are the lengths of the regions 222, 235, and 237 in the direction in which a current flows, may be the same offset length A2 in the single-side offset transistor and the double-side offset transistor. The offset length A1 may be set to, for example, 0.15 μm. The offset length A2 may be set to, for example, 0.6 μm. Each of the offset lengths A1 and A2 is not limited to the value described above, and an appropriate length is set in accordance with the characteristics required for each transistor. Alternatively, in the low-voltage operation transistor 210 and the high-voltage operation transistor 220, the offset lengths in the single-side offset transistor and the double-side offset transistor need not be set to one length. For example, in a specific circuit block of the peripheral circuit 200, the offset length is set longer than in another circuit block. With this, the hot carrier resistance is improved in the circuit block where the long offset length is set. A plurality of transistors of multiple different offset lengths may be mounted in each of the low-voltage operation transistor 210 and the high-voltage operation transistor 220.

The single-side offset transistor may be used in a circuit block in which, for example, a variable potential of GND to Vdd is applied to the drain side of the transistor but only the potential of GND is supplied to the source side. For example, the single-side offset transistor may be mounted in the vertical scanning circuit 102 or the like. Since the offset length on the source side can be decreased, the drivability of the transistor improves. In addition, since the device size is decreased, an effect of decreasing the chip circuit area can be obtained.

The double-side offset transistor may be used in a circuit block in which, for example, a variable potential is applied to both the drain side and source side of the transistor. For example, the double-side offset transistor may be mounted in the signal output circuit 104 or the like. In an application in which a variable potential is applied to both the drain side and the source side, by relaxing the electric field in the LDD portion (for example, the region 233, 234, 235, 237, or the like), a junction leakage between the drain and source and the well is suppressed, and the breakdown voltage between the source and the drain can be improved. As a result, an improvement in reliability is implemented.

In this manner, the single-side offset transistor and the double-side offset transistor are properly used in accordance with the characteristics required for the respective circuit blocks arranged in the light emitting device 150. This can further achieve both an improvement in reliability of the light emitting device 150 and an improvement in characteristics thereof.

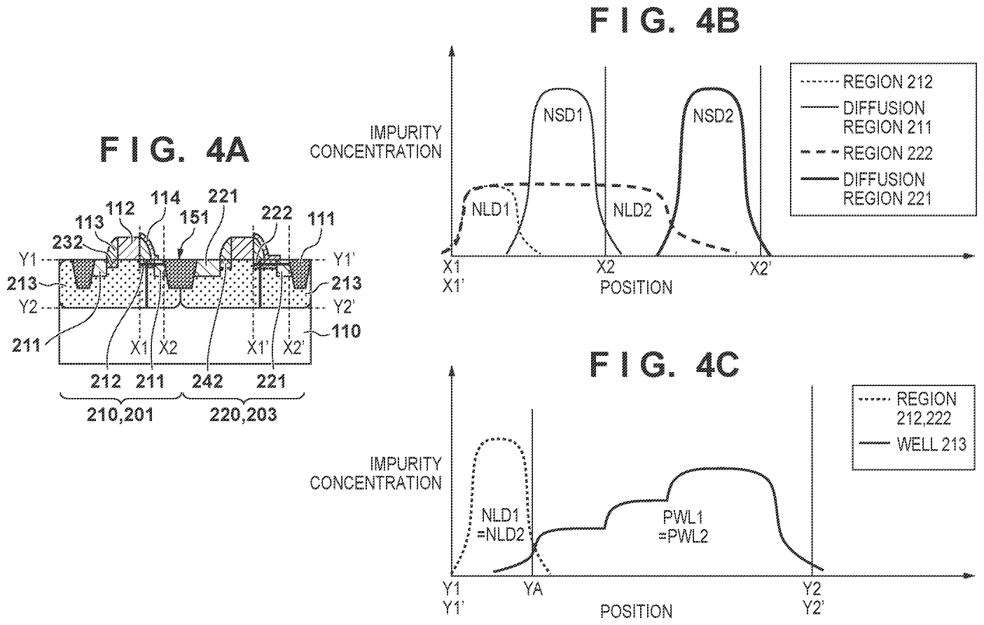

FIGS. 4A to 4C are views showing the distributions of the impurity concentrations of the transistor 201 and the transistor 203. The transistor 202 and the transistor 204 can have similar impurity distributions. FIG. 4B shows the impurity profile of the transistor 201 between X1 and X2 shown in FIG. 4A and the impurity profile of the transistor 203 between X1′ and X2′ shown in FIG. 4A by overlapping them with the positions of X1 and X1′ as the reference. FIG. 4C shows the impurity profile of the transistor 201 between Y1 and Y2 shown in FIG. 4A and the impurity profile of the transistor 203 between Y1′ and Y2′ shown in FIG. 4A by overlapping them with the positions of Y1 and Y1′ as the reference.

The abscissa of FIG. 4B represents the position in the direction along the surface 151 of the substrate 110 from X1 to X2 in the transistor 201, and the position in the direction along the surface 151 of the substrate 110 from X1′ to X2′ in the transistor 203. The ordinate of FIG. 4B represents the impurity concentration of each of the n-type region 212 and the n-type diffusion region 211 of the transistor 201, and the impurity concentration of each of the n-type region 222 and the n-type diffusion region 221 of the transistor 203. The region 212 and the region 222 have the same impurity concentration, and only the distance from X1 directly below the gate electrode 112 to X2 and the distance from X1′ directly below the gate electrode 112 to X2′ are different from each other. That is, FIG. 4B shows that the concentrations are the same but only the offset lengths are different between the LDD portions. This also applies to the diffusion region 211 and the diffusion region 221, and the diffusion regions 211 and 221 of the same impurity concentration are respectively formed at positions offset by the different offset length. On the other hand, comparing the impurity concentrations of the regions 212 and 222 with the impurity concentrations of the diffusion regions 211 and 221, the impurity concentrations of the diffusion regions 211 and 221 are higher than the impurity concentrations of the regions 212 and 222. For example, the impurity concentrations of the diffusion regions 211 and 221 may be about 100 to 10,000 times the impurity concentrations of the regions 212 and 222. With this, it is possible to implement the transistor in which the breakdown voltage is maintained but the drivability is less affected.

The abscissa of FIG. 4C represents the position in the depth direction from the surface 151 of the substrate 110 from Y1 to Y2 in the transistor 201, and the position in the depth direction from the surface 151 of the substrate 110 from Y1′ to Y2′ in the transistor 203. The ordinate of FIG. 4C represents the impurity concentration distribution of each of the n-type region 212 of the transistor 201, the n-type region 222 of the transistor 203, and the p-type well 213. The region 212 and the region 222 have the same impurity concentration also in the depth direction of the substrate 110, and also have the same impurity profile. When the impurity profile is the same, this means that the position of the p-n junction formed in the boundary between the n-type region 212 and the p-type well 213 and the position of the p-n junction formed in the boundary between the n-type region 222 and the p-type well 213 can be controlled within a range of, for example, 10 nm. That is, as has been described above, the depth of the region 212 is equal to the depth of the region 222. Therefore, the region 212 and the region 222 can be formed in the same step. Requirements necessary for forming the region 212 and the region 222 in the same step will be described later.

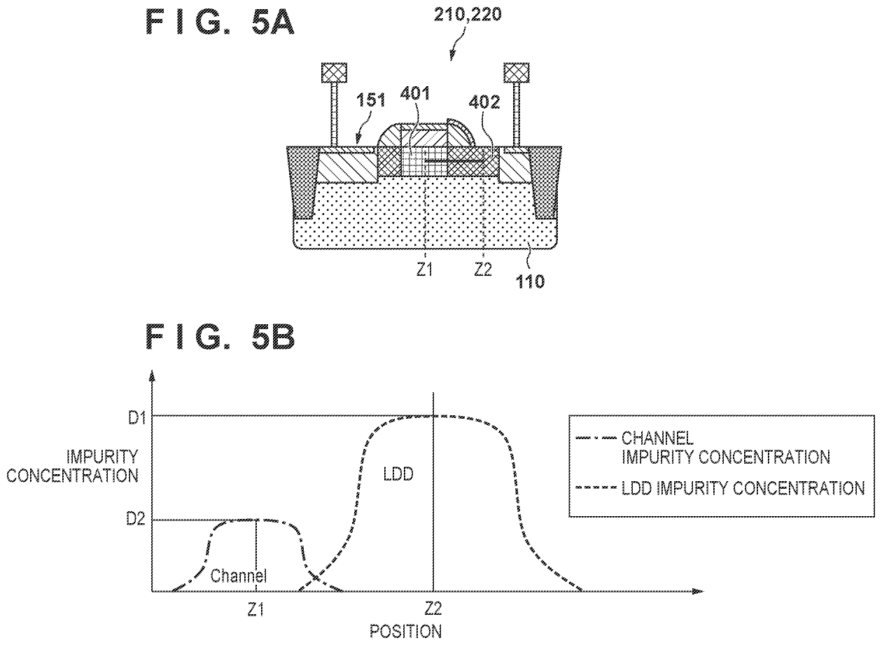

FIGS. 5A and 5B are views showing the distribution of impurity concentration while paying attention to a channel region 401 and a region 402 of the LDD structure of each of the low-voltage operation transistor 210 and the high-voltage operation transistor 220. The channel region 401 corresponds to, for example, the channel regions 251 to 254 described above, and the region 402 corresponds to, for example, the regions 212, 216, 222, and 224 described above. FIG. 5B shows the impurity profile of the low-voltage operation transistor 210 and the high-voltage operation transistor 220 including the portion between Z1 and Z2 shown in FIG. 5A.

The abscissa of FIG. 5B represents the position in the direction along the surface 151 of the substrate 110 including the portion from Z1 to Z2 in the low-voltage operation transistor 210 and the high-voltage operation transistor 220. The ordinate of FIG. 5B represents the impurity concentration of each of the channel region 401 and the region 402. In the n-type transistors (for example, the transistors 201 and 203), the channel region 401 is the p type, and the region 402 is the n type. An example will be described in which, in the p-type transistors (for example, the transistors 202 and 204), the channel region 401 is the p type and the region 402 is also the p type. FIG. 5B shows the maximum concentration of the impurity concentration of the region 402 as an impurity concentration D1, and the maximum concentration of the impurity concentration of the channel region 401 as an impurity concentration D2. Here, the above-described expression such as “the region 212 having a lower impurity concentration than the diffusion region 211” can be based on the comparison between the maximum concentrations of the respective impurity concentrations.

In each of the n-type transistors (for example, the transistors 201 and 203), the impurity concentration D1 of the region 402 may be nine times the impurity concentration D2 of the channel region 401 or less (D1/D2≤9). If the concentration ratio between the impurity concentration of the region 402 and the impurity concentration of the channel region 401 is excessively large, the threshold voltage of the transistor having different operation voltage becomes excessively low. On the other hand, if the concentration ratio is excessively low, the threshold voltage becomes excessively high. That is, it is necessary to form the channel region 401 and the region 402 within a range in which both the transistor characteristics of the low-voltage operation transistor 210 and those of the high-voltage operation transistor 220 can be compatible. Then, as has been described above, the region 212 and the region 222 can be formed in the same step, so that the number of steps of manufacturing the transistors 201 and 203 can be reduced.

In each of the p-type transistors (for example, the transistors 202 and 204), the impurity concentration D1 of the region 402 may be 100 times the impurity concentration D2 of the channel region 401 or more (D1/D2≥100). By suppressing the impurity concentration of the channel region 401 to be low, the variation of the impurity implantation in the surface of the channel region and carrier scattering due to interface states are suppressed, and the variation of the characteristics of the transistor in the subthreshold region can be suppressed. In addition, by keeping the impurity concentration of the region 402 to be high, when the power supply potential Vdd is applied to the drain end of the transistor, the spread of the depletion layer into the region 402 is suppressed. Then, generation of a p-n junction leakage current can be reduced, and a transistor with less variation can be implemented. On the other hand, a side effect of lowering the impurity concentration of the channel region 401 is that the threshold value becomes excessively low. As a countermeasure against this, it is possible to control the threshold voltage by adjusting the work function of the gate electrode 112, the offset length, and the gate length of the gate electrode 112 such that both of the transistor characteristics of the low-voltage operation transistor 210 and those of the high-voltage operation transistor 220 are compatible. With this, as has been described above, the region 216 and the region 224 can be formed in the same step, and the number of steps of manufacturing the transistors 202 and 204 can be reduced.

The above-described concentration relationship between the channel region 401 and the region 402 is applied. With this, in the low-voltage operation transistor 210 and the high-voltage operation transistor 220 having different operation voltages, it is possible to simultaneously form the region 402, the channel region 401, the wells (for example, the above-described well 213 and well 217), the diffusion regions (for example, the above-described diffusion regions 211, 221, 215, and 223) in each of the n-type transistor and the p-type transistor.

In this embodiment, in addition to the relationship of impurity concentration described above, the offset length is adjusted. For the n-type transistor, the transistor that operates at a higher voltage is more influenced by hot carriers. Therefore, for the transistor that is driven at a high voltage (for example, the high-voltage operation transistor 220), the offset length is increased to decrease the electric field intensity of the p-n junction between the region 402 and the well, thereby effectively reducing hot carriers. For the transistor that is driven at a low voltage (for example, the low-voltage operation transistor 210), by decreasing the offset length, it is possible to reduce the circuit area while suppressing a decrease of the ON current.

On the other hand, for the p-type transistors, the offset lengths of the low-voltage operation transistor 210 and the high-voltage operation transistor 220 can be made substantially equal. Holes, which are majority carriers in the p-type transistor, have an extremely low impact ionization coefficient as compared to electrons, so that hot carriers are less likely to occur. Therefore, there is little need to change the offset length in accordance with the operation voltage. Even if the offset length is shortened, the threshold can be adjusted by the gate length and work function of the gate electrode 112. The p-type transistor is often used in the pixel circuit 300, so that the size of the transistor is directly linked to the arrangement pitch of the pixels 101. Hence, by shortening the offset length, the pixel pitch is decreased, and this leads to an improvement in resolution of the light emitting device 150.

As has been described above, in the semiconductor device (light emitting device 150) including the low-voltage operation transistor 210 and the high-voltage operation transistor 220, the relationship of offset length as described above and the concentration relationship between the channel region and the LDD region are used. Thus, both an improvement in reliability of the transistor and an improvement in characteristics of the transistor are achieved. As a result, an improvement in reliability of the semiconductor device and an improvement in characteristics thereof are implemented. Further, the number of steps in the manufacture of the semiconductor device can be reduced, resulting in a cost reduction.

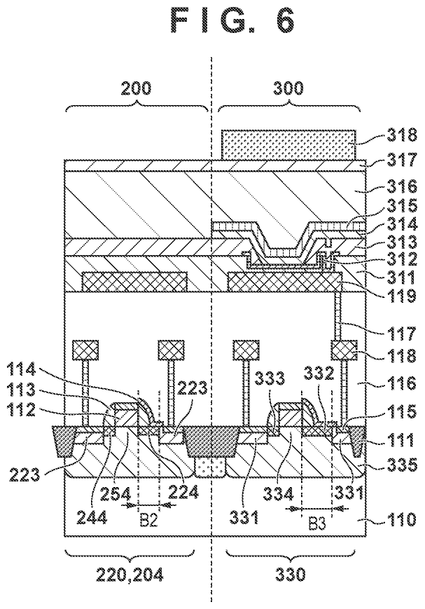

FIG. 6 shows an example of the sectional structure of elements mounted in the peripheral circuit 200 and the pixel circuit 300 of the light emitting device 150 in this embodiment. In the transistor 320 arranged in the pixel circuit 300 described above, the length of the region 322 and the length of the region 323 are the same in the direction in which a current flows through the transistor 320. However, the present invention is not limited to this, and a transistor in which the offset length of the LDD structure changes may be arranged in the pixel circuit 300. As the transistor arranged in the pixel circuit 300, FIG. 6 shows a transistor 330 which is a p-type MIS transistor.

The transistor 330 includes two p-type diffusion regions 331 functioning as the source or the drain, and p-type regions 332 and 333 each being arranged between the corresponding one of the two diffusion regions 331 and a channel region 334 and having a lower impurity concentration than the diffusion regions 331. It can also be said that the transistor 330 has an LDD structure including the low impurity concentration regions 332 and 333. In the direction in which a current flows through the transistor 330 (the horizontal direction in the arrangement shown in FIG. 6), the length of the region 332 is longer than the length of the region 333. The diffusion regions 331 and the regions 332 and 333 of the transistor 330 are formed in an n-type well 335 provided in the substrate 110.

Here, compare the above-described offset length B2 of the transistor 204, which is the p-type high-voltage operation transistor 220 arranged in the peripheral circuit 200, with an offset length B3 by which one diffusion region 331 is offset from directly below the gate electrode 112 in the p-type transistor 330 arranged in the pixel circuit 300. In this case, in the direction in which a current flows through each of the transistors 204 and 330, the length of the region 332 of the transistor 330 (offset length B3) may be longer than the length of the region 224 of the transistor 204 (offset length B2). In the pixel circuit 300, the offset length B3 of the transistor 330 is formed to be long. With this, the electric field is relaxed in the region 332, and it is possible to suppress a junction leakage between the region 332 and the well 335, and reduce the current variation in the sub-threshold region. The transistors formed in the pixel circuit 300 include a transistor in which the current flowing through the transistor directly flows to the functional layer 314 including the light emitting layer. The variation of the characteristics of such the transistor is directly linked to the display variation in the light emitting device 150. Therefore, the offset length B3 of the p-type transistor 330 arranged in the pixel circuit 300 is set to be longer than the offset length B2 of the p-type transistor 204 arranged in the peripheral circuit 200, thereby suppressing the variation of the characteristics of the transistor 330. With this, the luminance variation in display of the light emitting device 150 is reduced.

A plurality of transistors can be arranged in the pixel circuit 300 to operate one light emitting element. For example, for one light emitting element, a driving transistor that controls the current flowing through the light emitting element in accordance with a luminance signal supplied from the signal output circuit 104, a write transistor that writes the luminance signal in the driving transistor, a light emission control transistor that controls light emission or non-light emission of the light emitting element, a reset transistor that resets the light emitting element, and the like can be arranged. The transistor 330 may be used for these transistors. In this case, the offset length B3 may be individually changed in accordance with the kind of the transistor such as the driving transistor, the write transistor, the light emission control transistor, the reset transistor, or the like. Further, for example, for the reset transistor, in addition to adjusting the offset length B3, p-type polycrystalline silicon may be used for the gate electrode. When p-type polycrystalline silicon is used for the gate electrode, the threshold voltage can be lowered. Hence, it is possible to rapidly reset the potential of the anode electrode of the light emitting element.

Both the single-side offset transistor (the transistor 330) and the double-side offset transistor (for example, the transistor 320 descried above) may be arranged in the pixel circuit 300. The n-type transistor may also be arranged. Further, the gate length and the offset length may be changed to an appropriate combination. For example, in each conductivity type, the gate length of the transistor arranged in the pixel circuit 300 may be about twice the gate length of the transistor arranged in the peripheral circuit 200. Further, for example, the offset length of the transistor arranged in the pixel circuit 300 may be about 1.5 times the offset length of the transistor (for example, the high-voltage operation transistor 220) arranged in the peripheral circuit 200 in each conductivity type. With this, the variation of the characteristics of the transistor arranged in the pixel circuit can be suppressed, and the display quality in the light emitting device 150 can be improved.

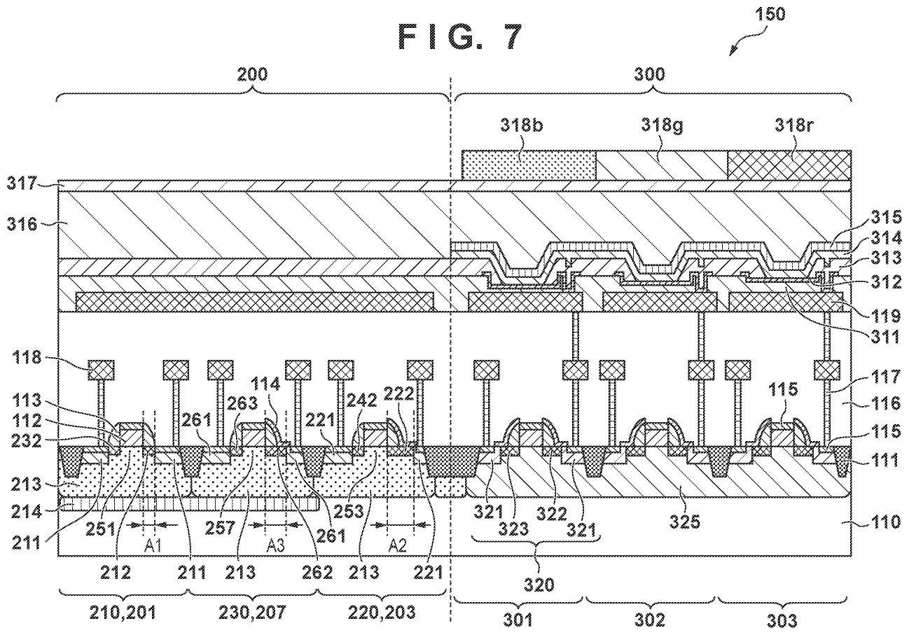

FIG. 7 shows an example of the sectional structure of elements mounted in the light emitting device 150 in this embodiment. In addition to the above-described low-voltage operation transistor 210 and high-voltage operation transistor 220, FIG. 7 shows a medium-voltage operation transistor 230. A higher voltage than the low-voltage operation transistor 210 is applied to the medium-voltage operation transistor 230, and the medium-voltage operation transistor 230 operates at the higher voltage than the low-voltage operation transistor 210. A lower voltage than the high-voltage operation transistor 220 is applied to the medium-voltage operation transistor 230, and the medium-voltage operation transistor 230 operates at the lower voltage than the high-voltage operation transistor 220. FIG. 7 shows the n-type transistor 201 as the low-voltage operation transistor 210, the n-type transistor 203 as the high-voltage operation transistor 220, and an n-type transistor 207 as the medium-voltage operation transistor 230. However, the present invention is not limited to this, and the p-type transistors may have a similar configuration.

The transistor 207 includes two n-type diffusion regions 261 functioning as the source or the drain, and n-type regions 262 and 263 each being arranged between the corresponding one of the two diffusion regions 261 and a channel region 257 and having a lower impurity concentration than the diffusion regions 261. In the direction in which a current flows through the transistor 207 (the horizontal direction in the arrangement shown in FIG. 7), the length of the region 262 is longer than the length of the region 263. The diffusion regions 261 and the regions 262 and 263 of the transistor 207 are formed in the p-type well 213 provided in the substrate 110.

As has been described above, the offset length A1 of the transistor 201 is, for example, 0.15 μm, and the offset length A2 of the transistor 203 is, for example, 0.6 μm. In this case, in the transistor 207 as the n-type medium-voltage operation transistor 230, an offset length A3 by which one diffusion region 261 is offset from directly below the gate electrode 112 may be set to, for example, 0.3 μm. In other words, the length of the region 262 in the direction in which a current flows in the transistor 207 may be 0.3 μm. In this manner, the offset length A1 of the low-voltage operation transistor 210, the offset length A3 of the medium-voltage operation transistor 230, and the offset length A2 of the high-voltage operation transistor 220 may have a relationship expressed by A1<A3<A2. Further, FIG. 7 shows the transistors 201, 203, and 207 which are the single-side offset transistors, but the present invention is not limited to this. The double-side offset transistors may be arranged as the low-voltage operation transistor 210, the medium-voltage operation transistor 230, and the high-voltage operation transistor 220. Also for the double-side offset transistors, the offset lengths may have the relationship expressed by the low-voltage operation transistor 210<the medium-voltage operation transistor 230<the high-voltage operation transistor 220.

For example, the low-voltage operation transistor 210 is a 1.2V-driven transistor, the medium-voltage operation transistor 230 is a 5V-driven transistor, and the high-voltage operation transistor 220 is a 10V-driven transistor. In this case, for the medium-voltage operation transistor 230 and the high-voltage operation transistor 220, the LDD portions (for example, the regions 222, 242, 262, and 263), the channel regions (for example, the channel region 253 and 257), the well (for example, the well 213), and the diffusion regions (for example, the diffusion regions 221, and 261) may be formed in the same step as has been described above. On the other hand, the low-voltage operation transistor 210 may be formed in an implantation step different from that for the medium-voltage operation transistor 230 and the high-voltage operation transistor 220. When the offset length A1 is largely different from the offset length A2, by separating the implantation step even for the same conductivity type, the controllability of each transistor improves. However, depending on the specifications of the low-voltage operation transistor 210, the medium-voltage operation transistor 230, and the high-voltage operation transistor 220, the impurity concentration and depth of the LDD portions (for example, the regions 262 and 263) of the medium-voltage operation transistor 230 may be set to the same impurity concentration and depth as the LDD portions (for example, the regions 212, 232, 222, and 242) of the low-voltage operation transistor 210 and the high-voltage operation transistor 220. Further, the impurity concentration and depth of the diffusion region (for example, the diffusion region 261) of the medium-voltage operation transistor 230 may be set to the same impurity concentration and depth as the diffusion regions (for example, the diffusion regions 211 and 221) of the low-voltage operation transistor 210 and the high-voltage operation transistor 220. For example, this applies to a case in which the low-voltage operation transistor 210 is a 3.3V-driven transistor, the medium-voltage operation transistor 230 is a 5V-driven transistor, and the high-voltage operation transistor 220 is a 10V-driven transistor.

In the arrangement shown in FIG. 7, the offset length of each of the low-voltage operation transistor 210, the medium-voltage operation transistor 230, and the high-voltage operation transistor 220 is individually set. With this, both an improvement in reliability of the transistor and an improvement in characteristics of the transistor are achieved, and as a result, improvements in reliability and characteristics of the semiconductor device are implemented. Further, the number of steps in the manufacture of the semiconductor device can be reduced, resulting in cost reduction.

Next, an example of a method of manufacturing the light emitting device 150 will be described using the arrangement shown in FIG. 2. First, the substrate 110 including STIs is prepared. In a step of forming the STIs 111, a hard mask including opening patterns in the regions where the STIs 111 are to be formed is first formed. The hard mask can be formed using polycrystalline silicon, silicon nitride, or the like. By etching the substrate 110 via the hard mask, trenches are formed. The depth of each trench is, for example, about 150 to 900 nm, and can be adjusted in accordance with the isolation breakdown voltage required for the region where the high-voltage operation transistor 220 is to be arranged. Then, an insulating film is formed along the inner wall on the side surface and bottom surface of the trench. The insulating film is formed by, for example, thermal oxidation in an oxidizing gas atmosphere. After that, an insulating body filling the trench is formed so as to cover the insulating film formed along the inner wall of the trench. For the insulating body filling the trench, for example, silicon oxide formed by a high-density plasma CVD method or the like may be used. Then, the insulating body is planarized by a combination of etching (etching-back) and CMP or the like. Thus, the STI 111 is formed. After that, a thermal oxide film is formed on the surface of the substrate 110. The thermal oxide film is provided for the purpose of suppressing channeling during ion implantation.

The STIs 111 may be formed to a uniform depth in the region of the peripheral circuit 200 where the low-voltage operation transistor 210 and the high-voltage operation transistor 220 are to be arranged, and the region where the pixel circuit 300 is to be formed. Alternatively, for example, the STIs 111 having different depths between the regions may be formed by forming a hard mask using polycrystalline silicon, silicon nitride, or the like in each region. Further, for example, a diffusion layer isolation portion formed by ion implantation may be formed in a boundary portion between the region where the low-voltage operation transistor 210 is to be arranged and the region where the high-voltage operation transistor 220 is to be formed.

After the STIs 111 are formed, for example, in a state in which a predetermined region is protected using a resist pattern or the like, multi-stage ion implantation is performed to form the p-type well 213. The multi-stage ion implantation for forming the well 213 can be performed within the range of, for example, the acceleration energy of about 10 to 2,000 keV and the dose amount of about 1×10¹¹ to 5×10¹³ cm⁻². In the multi-stage ion implantation for forming the well 213, the dose amount may be changed in accordance with the depth. For example, the well 213 of high concentration may be formed in the region shallower than the bottom portion of the STI 111, and the well 213 of low concentration may be formed in the region deeper than the bottom portion of the STI 111.

Next, after removing the resist pattern used in the ion implantation of the well 213 (a description of a step of removing the used resist pattern is omitted), for example, in a state in which a predetermined region is protected using a resist pattern or the like, multi-stage ion implantation for forming the n-type well 217 is performed. The multi-stage ion implantation for forming the well 217 can be performed within the range of, for example, the acceleration energy of about 10 to 2,000 keV and the dose amount of about 1×10¹¹ to 5×10¹³ cm⁻². In the multi-stage ion implantation for forming the well 217, the dose amount may be changed in accordance with the depth. For example, the well 217 of high concentration may be formed in the region shallower than the bottom portion of the STI 111, and the well 217 of low concentration may be formed in the region deeper than the bottom portion of the STI 111.

The p-type well 213 is formed in the regions where the n-type transistors (for example, the transistors 201 and 203) are to be formed. The n-type well 217 is formed in the regions where the p-type transistors (for example, the transistors 202 and 204) are to be formed. The ion implantation for forming the well 213 may be simultaneously performed in the region where the low-voltage operation transistor 210 is to be formed and the region where the high-voltage operation transistor 220 is to be formed. When performing the ion implantation for forming the well 213, ion implantation for forming the well of the n-type transistor to be arranged in the pixel circuit 300 may be simultaneously performed. Similarly, the ion implantation for forming the well 217 may be simultaneously performed in the region where the low-voltage operation transistor 210 is to be formed and the region where the high-voltage operation transistor 220 is to be formed. When performing the ion implantation for forming the well 217, ion implantation for forming the well (for example, the well 325) of the p-type transistor (for example, the transistor 320) to be arranged in the pixel circuit 300 may be simultaneously performed. However, the present invention is not limited to this, and ion implantation may be performed using another resist pattern only for an arbitrary region, and the depth and impurity concentration of ion implantation may be individually changed in each region.

Then, for example, in a state in which a predetermined region is protected using a resist pattern or the like, ion implantation for forming the n-type deep well 214 is performed. The ion implantation for forming the deep well 214 can be performed within the range of, for example, the acceleration energy of about 10 to 4,000 keV and the dose amount of about 5×10¹¹ to 1×10¹⁴ cm⁻².

After the ion implantations of the wells 213 and 217, the deep well 214, and the like, activation annealing for the ion-implanted dopants is sequentially performed. The ion implantation steps of the wells 213 and 217 and the deep well 214 need not always be performed in this order. For example, the ion implantations may be performed in the reversed order. In this case, when the ion implantation process of high acceleration is performed first, an amorphous layer is hardly formed on the surface (surface 151) of the substrate 110, and the controllability of ion implantation improves.

After the well 213 and 217 and the deep well 214 are formed, the gate insulating film and the gate electrode 112 are formed. For the gate insulating film, for example, silicon oxide formed by thermal oxidation or the like is used. The gate insulating film may be formed for the entire substrate 110 at once. In this case, for example, the thickness of the gate insulating film of the transistor 201 can be equal to the thickness of the gate insulating film of the transistor 203. In addition, the thicknesses of the gate insulating films of the low-voltage operation transistors 210 (for example, the transistors 201 and 202), the high-voltage operation transistors 220 (for example, the transistors 203 and 204), and the transistor (for example, the transistor 320) arranged in the pixel circuit can be equal to each other. However, the present invention is not limited to this, and an appropriate thickness of the gate insulating film may be selected for each region. For example, the thickness of the gate insulating film may be different between the peripheral circuit 200 and the pixel circuit 300. The gate electrode 112 is as has been described above.

After the gate insulating film and the gate electrode 112 are formed, for example, in a state in which predetermined regions are protected using a resist pattern or the like, ion implantation for forming the p-type regions 216, 236, 224, and 244 serving as the LDD portions is performed. The ion implantation for forming the regions 216, 236, 224, and 244 can be performed within the range of, for example, the acceleration energy of about 10 to 150 keV and the dose amount of about 1×10¹¹ to 5×10¹³ cm⁻². In the ion implantation for forming the regions 216, 236, 224, and 244, the dose amount may be changed in accordance with the depth. For the regions 216 and 236 and the regions 224 and 244, as has been described above, ion implantation may be collectively performed, using the same resist pattern, in predetermined regions of the low-voltage operation transistor 210 and predetermined regions of the high-voltage operation transistor 220.

Similarly, for example, in a state in which predetermined regions are protected using a resist pattern or the like, ion implantation for forming the n-type regions 212, 232, 222, and 242 serving as the LDD portions is performed. The ion implantation for forming the regions 212, 232, 222, and 242 can be performed within the range of, for example, the acceleration energy of about 10 to 150 keV and the dose amount of about 1×10¹¹ to 5×10¹³ cm⁻². In the ion implantation for forming the regions 212, 232, 222, and 242, the dose amount may be changed in accordance with the depth. For the regions 212 and 232 and the regions 222 and 242, as has been described above, ion implantation may be collectively performed, using the same resist pattern, in predetermined regions of the low-voltage operation transistor 210 and predetermined regions of the high-voltage operation transistor 220.

In this manner, the ion implantation can be simultaneously performed for the regions 216, 236, 224, and 244 and for the regions 212, 232, 222, and 242 in the regions where the low-voltage operation transistors 210 and the high-voltage operation transistors 220 are to be arranged. However, the present invention is not limited to this. For example, when the driving voltage of the low-voltage operation transistor 210 is largely different from that of the high-voltage operation transistor 220, the conditions for ion implantation may be individually set for the regions 216 and 236 and for the regions 224 and 244, and the ion implantation may be separately performed. Similarly, the conditions for ion implantation may be individually set for the regions 212 and 232 and the regions 222 and 242, and the ion implantation may be separately performed.

Also in the pixel circuit 300, ion implantation of the regions 322 and 323 serving as the LDD portions of the transistor 320 is performed. The ion implantation of the regions 322 and 323 may be simultaneously performed when the ion implantation for forming the regions 216, 236, 224, and 244 is performed. Further, ion implantation for forming the LDD portions of the n-type transistor to be arranged in the pixel circuit 300 may be simultaneously performed when the ion implantation for forming the regions 212, 232, 222, and 242 is performed. However, the present invention is not limited to this, and the conditions for ion implantation of the LDD portions of the transistor to be arranged in the pixel circuit 300 and the conditions for ion implantation of the LDD portions of the transistor to be arranged in the peripheral circuit 200 may be individually set, and the ion implantation may be separately performed.

Next, the side wall 113 of each of the transistors including the transistors 201 to 204 and 320 is formed. The side wall 113 may be formed by, for example, depositing silicon oxide or silicon nitride and etching them back. Alternatively, the side wall 113 may be formed by stacking silicon oxide and silicon nitride and etching them back. The side wall 113 may have a single-layer structure of silicon oxide or silicon nitride, or may have a stacked structure of silicon oxide and silicon nitride.

After the side wall 113 is formed, for example, in a state in which predetermined regions are protected using a resist pattern or the like, ion implantation for forming the n-type diffusion regions 211 and 221 is performed. The resist pattern for forming the diffusion regions 211 and 221 is formed such that ion implantation is not performed in the portion from directly below the gate electrode 112 to the predetermined region to form the transistor of the LDD structure (offset structure). The offset lengths A1 and A2 described above can be defined by the resist pattern used when performing the ion implantation for forming the n-type diffusion regions 211 and 221. The work function of the gate electrode 112 may be adjusted by forming an opening in the resist pattern in a predetermined region above the gate electrode 112 during the ion implantation of the diffusion regions 211 and 221. The ion implantation for forming the diffusion regions 211 and 221 can be performed within the range of, for example, the acceleration energy of about 5 to 30 keV and the dose amount of about 1×10¹³ to 7×10¹³ cm⁻². For the diffusion regions 211 and the diffusion regions 221, as has been described above, ion implantation may be collectively performed, using the same resist pattern, in predetermined regions of the low-voltage operation transistor 210 and predetermined regions of the high-voltage operation transistor 220.

Similarly, for example, in a state in which predetermined regions are protected using a resist pattern or the like, ion implantation for forming the p-type diffusion regions 215 and 223 is performed. The resist pattern for forming the diffusion regions 215 and 223 is formed such that ion implantation is not performed in the portion from directly below the gate electrode 112 to the predetermined region to form the transistor of the LDD structure (offset structure). The offset lengths B1 and B2 described above can be defined by the resist pattern used when performing the ion implantation for forming the p-type diffusion regions 215 and 223. The work function of the gate electrode 112 may be adjusted by forming an opening in the resist pattern in a predetermined region above the gate electrode 112 during the ion implantation of the diffusion regions 215 and 223. The ion implantation for forming the diffusion regions 215 and 223 can be performed within the range of, for example, the acceleration energy of about 3 to 30 keV and the dose amount of about 1×10¹¹ to 7×10¹⁵ cm⁻². For the diffusion regions 215 and the diffusion regions 223, as has been described above, ion implantation may be collectively performed, using the same resist pattern, in predetermined regions of the low-voltage operation transistor 210 and predetermined regions of the high-voltage operation transistor 220.

After the ion implantations of the regions 216, 236, 224, and 244, the regions 212, 232, 222, and 242, the diffusion regions 211 and 221, the diffusion regions 215 and 223, and the like are performed, activation annealing for the ion-planted dopants is sequentially performed.

Then, in each region in the peripheral circuit 200 and the pixel circuit 300, the silicide prevention film 114 for defining the region to form the silicide 115 is formed. For the silicide prevention film 114, for example, silicon oxide is used. The silicide prevention film 114 is arranged such that the silicide is not formed above the LDD portions such as the regions 212, 216, 222, 224, and the like.

After the silicide prevention film 114 is formed, the silicide 115 is formed by forming and annealing a metal such as titanium, tungsten, cobalt, or nickel. After the silicide 115 is formed, the interlayer insulating film 116 including the plug 117, the wiring pattern 118, and the electrode 119 is formed. A plurality of the wiring layers including the wiring patterns 118 may be arranged.

Then, in the pixel circuit 300, the optical adjustment layers 311 having different thicknesses to match the interference of the respective light emission wavelengths of the pixels 301 to 303 are formed. Further, on the optical adjustment layers 311, the electrodes 312, the pixel isolation layers 313 for isolating the pixels 301 to 303, the functional layer 314 including the light emission layer, and the electrode 315 are formed in this order. Further, on the electrode 315, the sealing film 316, the planarization layer 317, the blue color filter 318b, the green color filter 318g, the red color filter 318r, and the like are formed. With these steps, the light emitting device 150 is manufactured.

The light emitting device 150 need not always be manufactured with the above-described manufacturing method and step order, and replacement, change, and the like of various steps are possible. Further, the film thickness of the gate insulating film, the gate length, and the offset length may be individually changed in each region in the low-voltage operation transistor 210 and the high-voltage operation transistor 220. The above-described embodiment merely shows some aspects to which the present disclosure can be applied, and does not prevent appropriate modifications and changes in the range without departing from the scope of the present invention.

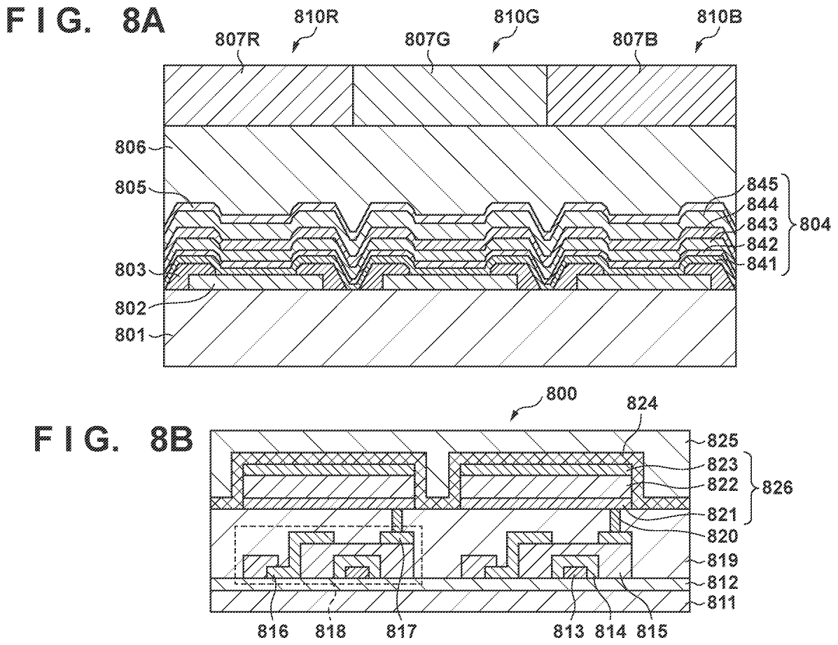

Here, application examples in which the semiconductor device serving as the light emitting device 150 according to the embodiment is applied to an image forming device, a display device, a photoelectric conversion device, an electronic apparatus, an illumination device, a moving body, and a wearable device will be described here with reference to FIGS. 8A to 16B. The description will be given assuming that, for example, an organic light emitting element such as an organic EL element is arranged as the light emitting element in the pixel 101 arranged in the pixel array 100 of the light emitting device 150 as has been described above. Details of each component arranged in the pixel array 100 of the light emitting device 150 described above will be described first, and the application examples will be described after that.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case in which a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of detects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in an arrangement including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this arrangement, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 8A shows an example of a pixel as a constituent element of the above-described pixel array 100. The pixel includes sub-pixels 810 (pixels 101). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display device 800 (corresponding to the above-described light emitting device 150) shown in FIG. 8B is provided with an organic light emitting element 826 and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 8B. That is, one of the anode and cathode and one of the source electrode and drain electrode of the TFT are electrically connected. The TFT indicates a thin-film transistor.

In the display device 800 shown in FIG. 8B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 8B but may be used as another switching element.

The transistor used in the display device 800 shown in FIG. 8B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 8B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polycrystalline silicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

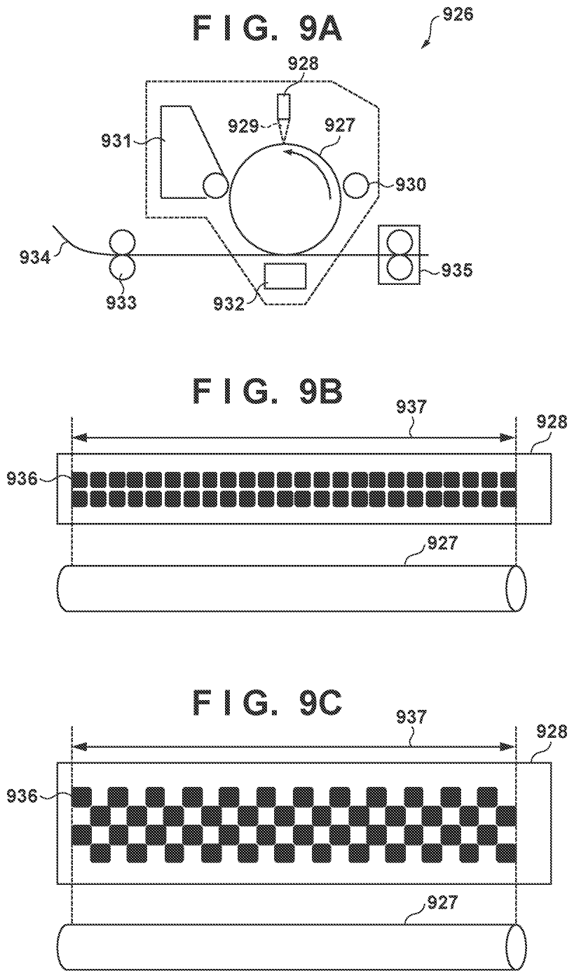

FIGS. 9A to 9C are schematic views showing an example of an image forming device using the light emitting device 150 according to this embodiment. An image forming device 926 shown in FIG. 9A includes a photosensitive member 927, an exposure light source 928, a developing unit 931, a charging unit 930, a transfer device 932, a conveyance unit 933 (a conveyance roller in the arrangement shown in FIG. 9A), and a fixing device 935.

Light 929 is emitted from the exposure light source 928, and an electrostatic latent image is formed on the surface of the photosensitive member 927. The light emitting device 150 can be applied to the exposure light source 928. The developing unit 931 can function as a developing device that contains a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper or a film. The fixing device 935 fixes the image formed on the print medium.

Each of FIGS. 9B and 9C is a schematic view showing a plurality of light emitting units 936 arranged along the longitudinal direction on a long substrate in the exposure light source 928. The light emitting device 150 can be applied to the light emitting units 936. That is, the plurality of pixels 101 arranged in the pixel array 100 are arranged along the longitudinal direction of the substrate. A direction 937 is a direction parallel to the axis of the photosensitive member 927. This column direction matches the direction of the axis upon rotating the photosensitive member 927. This direction 937 can be referred to as the long-axis direction of the photosensitive member 927.

FIG. 9B shows a form in which the light emitting units 936 are arranged along the long-axis direction of the photosensitive member 927. FIG. 9C shows a form, which is a modification of the arrangement of the light emitting units 936 shown in FIG. 9B, in which the light emitting units 936 are arranged in the column direction alternately between the first column and the second column. The light emitting units 936 are arranged at different positions in the row direction between the first column and the second column. In the first column, multiple light emitting units 936 are arranged spaced apart from each other. In the second column, the light emitting unit 936 is arranged at the position corresponding to the space between the light emitting units 936 in the first column. Also in the row direction, multiple light emitting units 936 are arranged spaced apart from each other. The arrangement of the light emitting units 936 shown in FIG. 9C can be referred to as, for example, an arrangement in a grid pattern, an arrangement in a staggered pattern, or an arrangement in a checkered pattern.

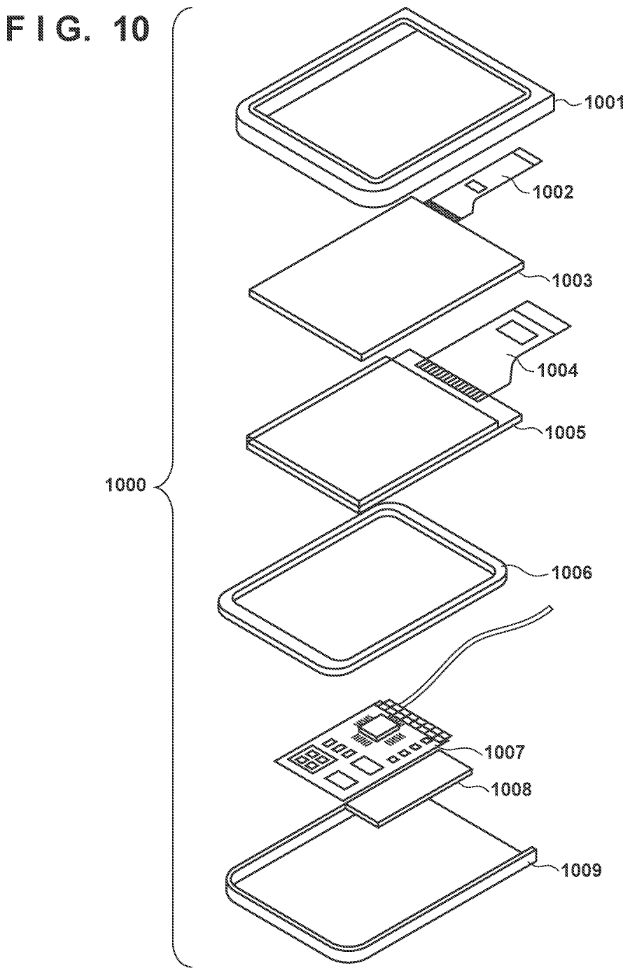

FIG. 10 is a schematic view showing an example of the display device using the light emitting device 150 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 150 can be applied to the display panel 1005. The pixels 101 arranged in the pixel array 100 of the light emitting device 150 functioning as the display panel 1005 operate in a state in which they are connected to the active elements such as transistors arranged on the circuit board 1007.

The display device 1000 shown in FIG. 10 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

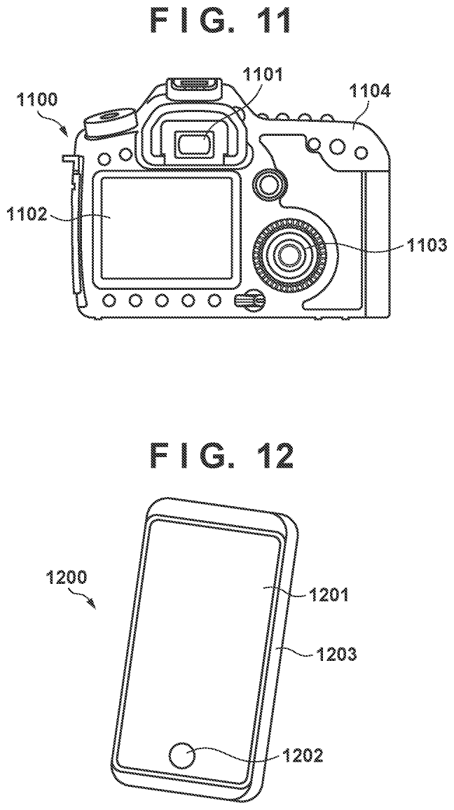

FIG. 11 is a schematic view showing an example of the photoelectric conversion device using the light emitting device 150 of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 150 according to this embodiment can be applied to the viewfinder 1101 or the rear display 1102 as a display unit. In this case, the pixel array 100 of the light emitting device 150 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 150 in which the pixel 101 including the light emitting element using the organic light emitting material such as an organic EL element is arranged in the pixel array 100 may be used for the viewfinder 1101 or the rear display 1102. This is so because the organic light emitting material has a high response speed. The light emitting device 150 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 150 may be applied to a display unit of an electronic apparatus. At this time, the display unit can have both a display function and an operation function. Examples of the portable terminal are a portable phone such as a smartphone, a tablet, and a head mounted display.

FIG. 12 is a schematic view showing an example of an electronic apparatus using the light emitting device 150 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 150 according to this embodiment can be applied to the display unit 1201.

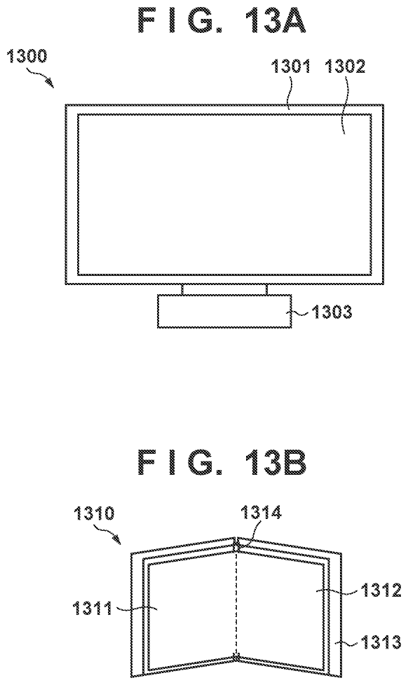

FIGS. 13A and 13B are schematic views showing examples of the display device using the light emitting device 150 of this embodiment. FIG. 13A shows a display device such as a television monitor or a PC monitor. A display device 1300 includes a frame 1301 and a display unit 1302. The light emitting device 150 according to this embodiment can be applied to the display unit 1302. The display device 1300 can include a base 1303 that supports the frame 1301 and the display unit 1302. The base 1303 is not limited to the form shown in FIG. 13A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 13B is a schematic view showing another example of the display device using the light emitting device 150 of this embodiment. A display device 1310 shown in FIG. 13B can be folded, and is a so-called foldable display device. The display device 1310 includes a first display unit 1311, a second display unit 1312, a housing 1313, and a bending point 1314. The light emitting device 150 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

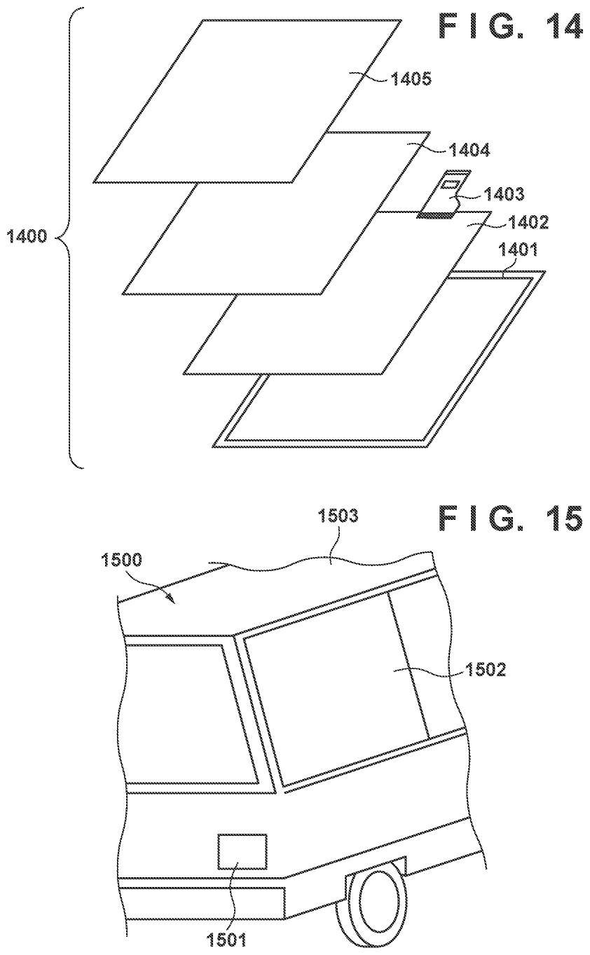

FIG. 14 is a schematic view showing an example of an illumination device using the light emitting device 150 according to this embodiment. An illumination device 1400 may include a housing 1401, a light source 1402, a circuit board 1403, an optical film 1404, and a light diffusion unit 1405. The light emitting device 150 according to this embodiment can be applied to the light source 1402. The optical film 1404 may be a filter that improves the color rendering property of the light source. The light diffusion unit 1405 can effectively diffuse light from the light source to illuminate a wide range for lighting up or the like. A cover may be provided in the outermost portion, as needed. The illumination device 1400 may include both the optical film 1404 and the light diffusion unit 1405, or may include only one of them.

The illumination device 1400 is, for example, a device that illuminates a room. The illumination device 1400 may emit light of white, day white, or any other color from blue to red. The illumination device 1400 may include a light control circuit for controlling the light color. The illumination device 1400 may include a power supply circuit connected to the light emitting device 150 which functions as the light source 1402. The power supply circuit is a circuit that converts an AC voltage into a DC voltage. Note that white light has a color temperature of 4200K, and day-white light has a color temperature of 5000K. The illumination device 1400 may also include a color filter. Further, the illumination device 1400 may include a heat dissipation portion. The heat dissipation portion releases the heat in the device to the outside of the device, and examples thereof include a metal having high specific heat, liquid silicon, and the like.

FIG. 15 is a schematic view showing an automobile including a tail lamp which is an example of the lighting unit for an automobile using the light emitting device 150 according to this embodiment. An automobile 1500 includes a tail lamp 1501, and may turn on the tail lamp 1501 when a brake operation or the like is performed. The light emitting device 150 according to this embodiment may be used in a head lamp as the lighting unit for an automobile. The automobile is an example of a moving body, and the moving body may be a ship, a drone, an aircraft, a railroad car, an industrial robot, or the like. The moving body may include a body and a lighting unit provided in the body. The lighting unit may inform the current position of the body.

The light emitting device 150 according to this embodiment can be applied to the tail lamp 1501. The tail lamp 1501 may include a protective member that protects the light emitting device 150 which functions as the tail lamp 1501. The protective member has a certain degree of strength, and can be made from any material as long as it is transparent. The protective member may be made from polycarbonate or the like. Further, the protective member may be made from polycarbonate mixed with furandicarboxylic acid derivative, acrylonitrile derivative, or the like.

The automobile 1500 may include a body 1503 and windows 1502 attached thereto. The window may be a window for checking the front or rear of the automobile, or may a transparent display such as a head-up display. The light emitting device 150 according to this embodiment may be used in the transparent display. In this case, the components such as the electrodes included in the light emitting device 150 are formed by transparent members.

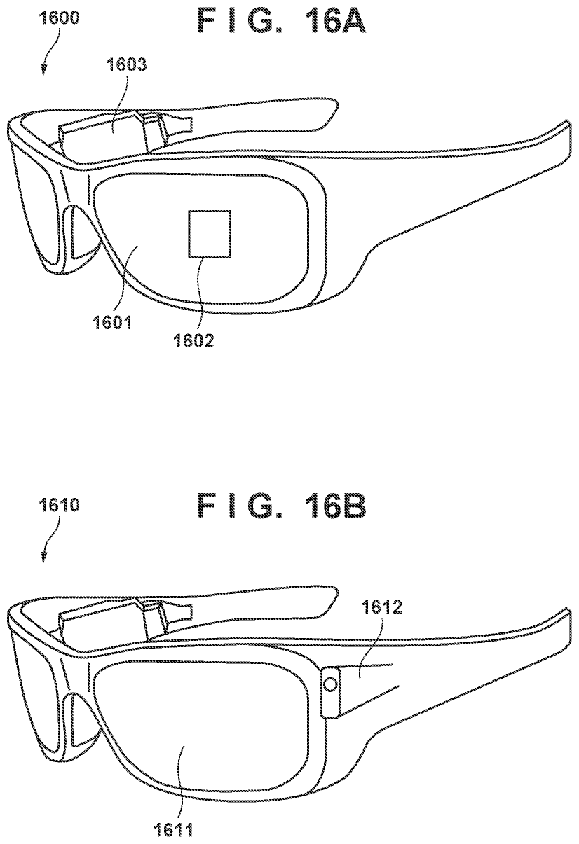

Further application examples of the light emitting device 150 according to this embodiment will be described with reference to FIGS. 16A and 16B. The light emitting device 150 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 16A. An image capturing device 1602 such as a CMOS sensor or an SPAD is provided on the surface side of a lens 1601 of the glasses 1600. In addition, the light emitting device 150 according to this embodiment is provided on the back surface side of the lens 1601.

The glasses 1600 further include a control device 1603. The control device 1603 functions as a power supply that supplies electric power to the image capturing device 1602 and the light emitting device 150 according to each embodiment. In addition, the control device 1603 controls the operations of the image capturing device 1602 and the light emitting device 150. An optical system configured to condense light to the image capturing device 1602 is formed on the lens 1601.

Glasses 1610 (smartglasses) according to one application example will be described with reference to FIG. 16B. The glasses 1610 include a control device 1612, and an image capturing device corresponding to the image capturing device 1602 and the light emitting device 150 are mounted on the control device 1612. The image capturing device in the control device 1612 and an optical system configured to project light emitted from the light emitting device 150 are formed in a lens 1611, and an image is projected to the lens 1611. The control device 1612 functions as a power supply that supplies electric power to the image capturing device and the light emitting device 150, and controls the operations of the image capturing device and the light emitting device 150. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 150 according to the embodiment of the present disclosure can include an image capturing device including a light receiving element, and control a displayed image based on the line-of-sight information of the user from the image capturing device.

More specifically, the light emitting device 150 decides a first visual field region at which the user is gazing and a second visual field region other than the first visual field region based on the line-of-sight information. The first visual field region and the second visual field region may be decided by the control device of the light emitting device 150, or those decided by an external control device may be received. In the display region of the light emitting device 150, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 150, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 150, the image capturing device, or an external device. If the external device holds the AI program, it is transmitted to the light emitting device 150 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-022639, filed Feb. 16, 2023, which is hereby incorporated by reference herein in its entirety.

What is claimed is:

1. A semiconductor device in which a first transistor and a second transistor having different operation voltages are arranged in a substrate, wherein
the first transistor comprises a first region and a second region each being arranged between corresponding one of two diffusion regions functioning as one of a source and a drain and a channel region and having a lower impurity concentration than the two diffusion regions of the first transistor, and a first length of the first region is longer than a second length of the second region in a direction in which a current flows through the first transistor,
the second transistor comprises a third region and a fourth region each being arranged between corresponding one of two diffusion regions functioning as one of a source and a drain and a channel region and having a lower impurity concentration than the two diffusion regions of the second transistor, and a third length of the third region is longer than a fourth length of the fourth region in a direction in which a current flows through the second transistor,
a depth of the first region is equal to a depth of the third region, and the third length is longer than the first length, and
a higher voltage than the first transistor is applied to the second transistor.

2. The device according to claim 1, wherein
the impurity concentration of the first region is equal to the impurity concentration of the third region.

3. The device according to claim 1, wherein
the second length is equal to the fourth length.

4. The device according to claim 1, wherein
a difference between a maximum voltage applied to the first transistor and a maximum voltage applied to the second transistor is not less than 5 V.

5. The device according to claim 1, wherein
the third length is longer than the first length by not less than 0.4 μm.

6. The device according to claim 1, wherein
a thickness of a gate insulating film of the first transistor is equal to a thickness of a gate insulating film of the second transistor.

7. The device according to claim 1, wherein
each of the first transistor and the second transistor is an n-type transistor.

8. The device according to claim 7, wherein
the impurity concentration of the first region is not more than nine times an impurity concentration of the channel region of the first transistor, and
the impurity concentration of the third region is not more than nine times an impurity concentration of the channel region of the second transistor.

9. The device according to claim 8, further comprising a p-type third transistor and a p-type fourth transistor arranged in the substrate,
the third transistor comprises a fifth region and a sixth region each being arranged between corresponding one of two diffusion regions functioning as one of a source and a drain and a channel region and having a lower impurity concentration than the two diffusion regions of the third transistor, and a fifth length of the fifth region is equal to a sixth length of the sixth region in a direction in which a current flows through the third transistor,
the fourth transistor comprises a seventh region and an eighth region each being arranged between corresponding one of two diffusion regions functioning as one of a source and a drain and a channel region and having a lower impurity concentration than the two diffusion regions of the fourth transistor, and a seventh length of the seventh region is equal to an eighth length of the eighth region in a direction in which a current flows through the fourth transistor, and
a depth of the fifth region is equal to a depth of the seventh region, and the seventh length is longer than the fifth length.

10. The device according to claim 1, wherein
each of the first transistor and the second transistor is a p-type transistor.

11. The device according to claim 10, wherein
the impurity concentration of the first region is not less than 100 times an impurity concentration of the channel region of the first transistor, and
the impurity concentration of the third region is not less than 100 times an impurity concentration of the channel region of the second transistor.

12. The device according to claim 10, further comprising an n-type third transistor and an n-type fourth transistor arranged in the substrate,
the third transistor comprises a fifth region and a sixth region each being arranged between corresponding one of two diffusion regions functioning as one of a source and a drain and a channel region and having a lower impurity concentration than the two diffusion regions of the third transistor, and a fifth length of the fifth region is longer than a sixth length of the sixth region in a direction in which a current flows through the third transistor,
the fourth transistor comprises a seventh region and an eighth region each being arranged between corresponding one of two diffusion regions functioning as one of a source and a drain and a channel region and having a lower impurity concentration than the two diffusion regions of the fourth transistor, and a seventh length of the seventh region is longer than an eighth length of the eighth region in a direction in which a current flows through the fourth transistor, and
a depth of the fifth region is equal to a depth of the seventh region, and the seventh length is longer than the fifth length.

13. A semiconductor device in which a first transistor and a second transistor of a first conductivity type and a third transistor and a fourth transistor of a second conductivity type different from the first conductivity type are arranged in a substrate, wherein
operation voltages of the first transistor and the third transistor are different from operation voltages of the second transistor and the fourth transistor,
the first transistor comprises a first region and a second region each being arranged between corresponding one of two diffusion regions functioning as one of a source and a drain and a channel region, and having a lower impurity concentration than the two diffusion regions of the first transistor, and a first length of the first region is longer than a second length of the second region in a direction in which a current flows through the first transistor,
the second transistor comprises a third region and a fourth region each being arranged between corresponding one of two diffusion regions functioning as one of a source and a drain and a channel region and having a lower impurity concentration than the two diffusion regions of the second transistor, and a third length of the third region is longer than a fourth length of the fourth region in a direction in which a current flows through the second transistor,
the third transistor comprises a fifth region and a sixth region each being arranged between corresponding one of two diffusion regions functioning as one of a source and a drain and a channel region and having a lower impurity concentration than the two diffusion regions of the third transistor, and a fifth length of the fifth region is longer than a sixth length of the sixth region in a direction in which a current flows through the third transistor,
the fourth transistor comprises a seventh region and an eighth region each being arranged between corresponding one of two diffusion regions functioning as one of a source and a drain and a channel region and having a lower impurity concentration than the two diffusion regions of the fourth transistor, and a seventh length of the seventh region is longer than an eighth length of the eighth region in a direction in which a current flows through the fourth transistor, and
in the direction, a difference between the first length and the third length is larger than a difference between the fifth length and the seventh length.

14. The device according to claim 13, wherein
a higher voltage than the first transistor and the third transistor is applied to the second transistor and the fourth transistor.

15. The device according to claim 13, wherein
the first conductivity type is an n type.

16. The device according to claim 1, wherein
a pixel circuit, in which a plurality of pixels each comprising a light emitting element are arranged, and a peripheral circuit configured to drive the plurality of pixels are arranged in the substrate, and
the first transistor and the second transistor are arranged in the peripheral circuit.

17. The device according to claim 16, wherein
a gate electrode of each of the first transistor and the second transistor is formed of n-type polycrystalline silicon.

18. The device according to claim 17, wherein
an impurity concentration of the polycrystalline silicon is not less than 1×10²¹ cm⁻³.

19. The device according to claim 16, further comprising a fifth transistor arranged in the pixel circuit and having the same conductivity type as the first transistor,
wherein the fifth transistor comprises a ninth region and a tenth region each being arranged between corresponding one of two diffusion regions functioning as one of a source and a drain and a channel region and having a lower impurity concentration than the two diffusion regions of the fifth transistor, and a ninth length of the ninth region is longer than a tenth length of the tenth region in a direction in which a current flows through the fifth transistor, and
a depth of the first region is equal to a depth of the ninth region, and the ninth length is longer than the first length.

20. The device according to claim 16, further comprising a fifth transistor arranged in the pixel circuit,
wherein the fifth transistor comprises a ninth region and a tenth region each being arranged between corresponding one of two diffusion regions functioning as one of a source and a drain and a channel region and having a lower impurity concentration than the two diffusion regions of the fifth transistor, and a ninth length of the ninth region is equal to a tenth length of the tenth region in a direction in which a current flows through the fifth transistor, and
the ninth length is longer than the first length.

21. The device according to claim 1, wherein
a pixel circuit, in which a plurality of pixels each comprising a light emitting element are arranged, and a peripheral circuit configured to drive the plurality of pixels are arranged in the substrate,
the first transistor is arranged in the peripheral circuit, and
the second transistor is arranged in the pixel circuit.

22. A photoelectric conversion device comprising an optical unit comprising a plurality of lenses, an image sensor configured to receive light having passed through the optical unit, and a display unit configured to display an image,
wherein the display unit displays an image captured by the image sensor, and comprises the semiconductor device according to claim 16.

23. An electronic apparatus comprising a housing provided with a display unit, and a communication unit provided in the housing and configured to perform external communication,
wherein the display unit comprises the semiconductor device according to claim 16.
